(19) United States
(12) Patent Application Publication
(10) Pub. No.: US 2011/0094576 A1
(43) Pub. Date: Apr. 28, 2011

(54) STRUCTURE AND PROCESS FOR SOLAR CELL ELECTRODES

(76) Inventors: James R. Sheats, Palo Alto, CA (US); Phil Stob, Fremont, CA (US)

(21) Appl. No.: 12/786,400

(22) Filed: May 24, 2010

Related U.S. Application Data
(60) Provisional application No. 61/180,817, filed on May 22, 2009.

(51) Int. Cl. H01L 31/0224

(52) U.S. Cl. 136/256

(57) ABSTRACT

Methods and devices are described for thin film solar cell manufacturing. In one embodiment, the method includes displacing the residual insulator in vias with the pins of the present invention, which may greatly reduce the amount of material to be removed and hence make the laser more cost-effective. It is still desirable to use a laser or other device to completely clear the bottom of the via of residual material (to prepare for making a good electrical connection) but the film remaining under the pins would be microns in thickness, compared to the hundreds of microns of via depth.

### CROSS-REFERENCE TO RELATED APPLICATION

This application claims priority to U.S. Provisional Application Ser. No. 61/180,817 filed May 22, 2009 and fully incorporated herein by reference for all purposes.

This invention was made with Government support under Contract No. DE-FC36-07G017047 awarded by the Department of Energy. The Government has certain rights in this invention.

### FIELD OF THE INVENTION

This invention relates to solar cells and more specifically to solar cell electrode.

### BACKGROUND OF THE INVENTION

There is a need for a solar cell with improved solar cell electrodes.

### SUMMARY OF THE INVENTION

The disadvantages associated with the prior art are overcome by embodiments of the present invention. Embodiments of the invention may be used for high throughput, high precision manufacturing for roll-to-roll production systems. The embodiments are applicable to various thin film absorbers such as but not limited to polycrystalline CIGS (copper indium gallium di-selenide, but not excluding any other of the IB, IIIA, VIA elements like e.g. aluminum, and sulfur).

A further understanding of the nature and advantages of the invention will become apparent by reference to the remaining portions of the specification and drawings.

### BRIEF DESCRIPTION OF THE DRAWINGS

FIG. 1 shows one embodiment of the present invention.

FIG. 2 shows one embodiment of the present invention.

FIG. 3 shows one embodiment of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for a barrier film, this means that the barrier film feature may or may not be present, and, thus, the description includes both structures wherein a device possesses the barrier film feature and structures wherein the barrier film feature is not present.

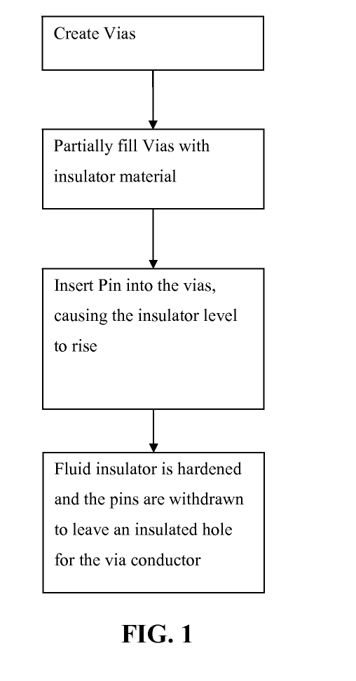

ABSTRACT/BRIEF SUMMARY: An array of low surface energy pins is constructed whose spacing is equal to the via spacing for a back contact structure. In one embodiment, the pin diameter is less than the via diameter, and its length is about equal to the depth of the via in a laminated cell, plus some amount for mounting the pin. After the vias have been partially filled with an insulator, the pins are lowered into the vias, causing the insulator level to rise and overflow the top of the via. The fluid insulator is then hardened and the pins are withdrawn to leave an insulated hole for the via conductor. FIG. 1 shows one embodiment of the method.

WHAT IS/ARE THE KEY INNOVATION(S), IMPROVEMENTS, ETC.: By displacing the residual insulator with the pins of the present invention, one may greatly reduce the amount of material to be removed and hence make the laser more cost-effective. It is still desirable to use a laser to completely clear the bottom of the via of residual material (to prepare for making a good electrical connection) but the film remaining under the pins would be microns in thickness, compared to the hundreds of microns of via depth.

DESCRIBE THE KEY ELEMENTS OF THE INVENTION: In one nonlimiting example, the pins may have flat ends and be of uniform length so as to press down uniformly over the entire cell. They will be coated with something to prevent them from sticking to the insulator as it is being cured; a teflon-like film, applied by plasma deposition or hot wire CVD, for example, will be suitable. The mounting structure for the pins should not obscure the insulator from radiation, heat, or energy coming from above. Thin metal beams (as narrow as the pins but relatively high) would be stiff enough, when composed in an array. Alternatively, the pins may be mounted in a quartz plate. The pins may be constructed of metal, glass or other stable machinable solid materials.

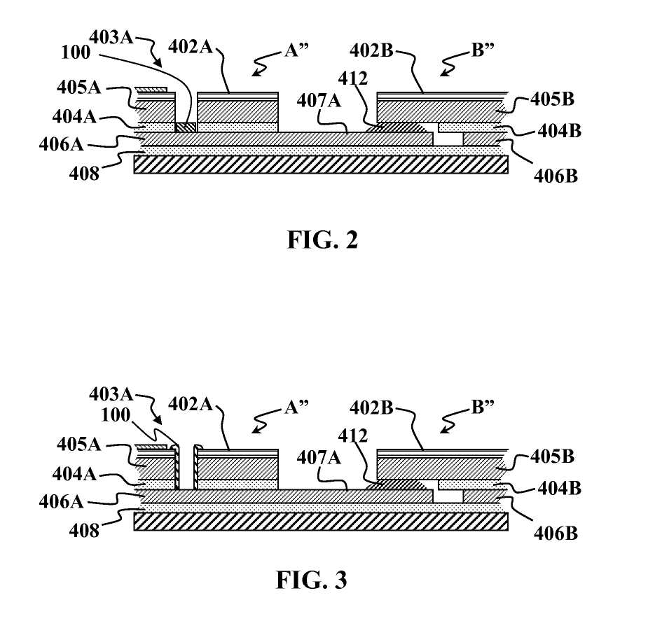

FIGS. 2-3 depict one embodiment of a solar cell with a plurality of vias. First and second device cells A″, B″ are assembled from pre-cut device layers 402A, 402B, insulating layers 404A, 404B and back plane layers 406A, 406B and attached to a carrier substrate 408. Insulated electrical contacts 403A make electrical contact through the device layers 402A, a bottom electrode 405A and the insulating layer 406A as shown in FIG. 2. Front edges of the insulating layer 404B and back plane 406B of module B″ are cut back (or formed in this configuration) with respect to the device layer 402B. To facilitate electrical contact, however, a back edge of the back plane 406A of cell A″ extends beyond the back edges of the device layer 402A and insulating layer 404A. As a result, the device layer 402B of cell B″ overlaps the back plane 406A of module A″. A ridge of conductive adhesive 412 on an exposed portion 407A of the back plane 406A makes electrical contact with an exposed portion of a bottom electrode 405B of the device layer 402B as shown in FIG. 2. The connection at 412 can optionally be formed by other methods such as but not limited to soldering or the like. Optionally, some may remove the element 412 and form the connection by welding such as but not limited to laser welding, ultrasonic welding, spot welding, or other electrical joining techniques. Some embodiments may weld from the backside of cells, through the layer to create the joint between the cells at where reference 412 number is located.

FIG. 2 shows that the via is partially filled by the material 100 such as but not limited to a insulator to coat the side walls of the. The pin is inserted into the material 100 and causes it to overflow.

FIG. 3 shows that optionally, that the material 100 extends along the length of the side wall of the via and covers at the least the upper corners.

5. DESCRIBE THE KEY ADVANTAGES OF THE INVENTION: The cost of the process is substantially reduced, and the range of materials which may be suitable for the insulator is increased since coatability is no longer a primary consideration.

6. DESCRIBE OPTIONS/ALTERNATIVE EMBODIMENTS: There are probably many ways to make the pin structure. For example, if a quartz mounting plate is used, the structure might be a single piece, and the pins formed by lithography and etching. Alternatively the pins can be press fitted into holes, or a framework of thin beams can be used as mentioned above. There are also multiple way to prepare the pin surfaces to prevent sticking Besides fluorocarbon films deposited from vapors, self-assembled monolayers and ultrathin polymer films adsorbed from solution would be suitable. By way of example and not limitation, the pins could also be made of solid fluoropolymer or similar substance.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, it should be understood that they are not limited to any one type of thin-film absorber material. They may be formed in roll to roll or in batch configuration. By way of nonlimiting example, the attachment of two metal layers is of use in embodiments such as those found in U.S. patent application Ser. No. 11/207,157 (Attorney Docket NSL-043). Fusing equipment may be found with reference to DELA Incorporated 175 Ward Hill Avenue Ward Hill, Mass.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, copper-indium-gallium-selenium (for CIGS solar cells), CdSe, CdTe, Cu(In,Ga)(S,Se)₂, Cu(In,Ga,Al)(S,Se,Te)₂, Cu—In, In—Ga, Cu—Ga, Cu—In—Ga, Cu—In—Ga—S, Cu—In—Ga—Se, other absorber materials, II-VI materials, IB-VI materials, CuZnTe, CuTe, ZnTe, IB-IIB-IVA-VIA absorbers, or other alloys, other absorber materials, IB-IIB-IVA-VIA absorber solar cells, or other alloys and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A solar cell electrode.
